(19) United States
(12) Patent Application Publication
(10) Pub. No.: US 2017/0338193 A1
(43) Pub. Date: Nov. 23, 2017

(54) POWER SEMICONDUCTOR MODULE WITH SHORT-CIRCUIT FAILURE MODE

(71) Applicant: DANFOSS SILICON POWER GMBH, Flensburg (DE)

(72) Inventors: Josef Lutz, Chemnitz (DE); Ronald Eisele, Surendorf (DE); Jacek Rudzki, Kiel (DE); Martin Becker, Kiel (DE); Mathias Kock, Gokels (DE); Frank Osterwald, Kiel (DE)

(21) Appl. No.: 15/520,872

(22) PCT Filed: Oct. 14, 2015
(86) PCT No.: PCT/EP2015/073745

§ 371 Date: Apr. 21, 2017

(30) Foreign Application Priority Data
Oct. 24, 2014 (DE) 10 2014 221 687.7

(51) Int. Cl. H01L 23/62; H01L 23/00

(52) U.S. Cl. CPC H01L 23/62; H01L 24/48; H01L 24/07; H01L 24/04; H01L 24/45; H01L 2224/45124; H01L 2924/13055

(57) ABSTRACT

A description is given of a power semiconductor module 10 which can be transferred from a normal operating mode to an explosion-free robust short-circuit failure mode. Said power semiconductor module 10 comprises a power semiconductor 1 having metallizations 3 which form potential areas and are separated by insulations and passivations on the top side 2 of said power semiconductor. Furthermore, an electrically conductive connecting layer is provided, on which at least one metal shaped body 4 which has a low lateral electrical resistance and is significantly thicker than the connecting layer is arranged, said at least one metal shaped body being applied by sintering of the connecting layer such that said metal shaped body is cohesively connected to the respective potential area. The metal shaped body 4 is embodied and designed with means for laterally homogenizing a current flowing through it in such a way that a lateral current flow component 5 is maintained until this module switches off in order to avoid an explosion, wherein the metal shaped body 4 has connections 6 having high-current capability. A transition from the operating mode to the robust failure mode then takes place in an explosion-free manner by virtue of the fact that the connections 6 are contact-connected and dimensioned in such a way that in the case of overload currents of greater than a multiple of the rated current of the power semiconductor 1, the operating mode changes to the short-circuit failure mode with connections 6 remaining on the metal shaped body 4 in an explosion-free manner without the formation of arcs.

### CROSS-REFERENCE TO RELATED APPLICATIONS

This application is a National Stage application of International Patent Application No. PCT/EP2015/073745, filed on Oct. 14, 2015, which claims priority to German Patent Application No. 102014221687.7, filed on Oct. 24, 2014, each of which is hereby incorporated by reference in its entirety.

### TECHNICAL FIELD

The invention relates to a power semiconductor module and a power semiconductor structure comprising such a power semiconductor module with a robust short-circuit failure mode.

### BACKGROUND

In power electronics, semiconductor components such as e.g. insulated gate bipolar transistors (IGBTs) are used for diverse applications such as e.g. for control units for wind power installations. The advantages of an IGBT consist in a good on-state behaviour, a high reverse voltage and a certain robustness. An IGBT utilizes the advantages of a field effect transistor with its virtually power-free driving and also has a certain robustness with respect to short circuits, since the IGBT limits the load current.

During the operation of power semiconductor modules, overloading and failure can occur for diverse reasons such as e.g. external faults. Upon the failure of a power semiconductor module having top-side connections by means of bonding wires, an arc often occurs after the melting of the bonding wires upon the failure, said arc resulting in an explosion of the module. For a number of fields of application of the IGBTs in the high-power range, increased requirements are made with regard to an explosion-free behaviour, or at least a behaviour that reduces the consequences of an explosion. The abovementioned semiconductor components are interconnected in larger units owing to the high powers to be switched in the field of large installations, which can lead to the total failure of larger power units particularly in the event of an explosion of an individual semiconductor component. Besides the direct damage caused by the explosion, the contamination of entire large units with the silicone potting compound particles or vapours of the exploded module that are distributed over all surfaces as a result of the explosion is considered to be particularly harmful in this case. The repair of a unit damaged and contaminated in this way would be virtually impossible, since all contacts and surfaces would have to be cleaned in the context of the repair, which would be extremely costly.

The previous developments are oriented primarily towards improved producibility and improved thermal loading capacity, while the minimization of the adverse influences of explosions of power semiconductor modules has been directed only to combating their symptoms, but not to avoiding their causes. By way of example, there is an impetus to making the explosion of a module manageable by the housing being designed with “predetermined breaking locations” to the effect that the emission of particles and vapours is directed in specific directions and does not take place in an uncontrolled manner in all directions.

EP 0 520 294 A1 describes a semiconductor component and a method for producing it, said semiconductor component comprising on its top side an additional body serving as a heat buffer and consisting of a highly thermally conductive material, said additional body having an increased loading capacity with respect to additional thermal loading pulses. Furthermore, WO 2013/053420 A1 and WO 2013/053419 A1 disclose a power semiconductor chip comprising metal shaped bodies for making contact with thick wires or ribbons, and a method for producing it. The primary orientation here is towards longevity and robust modules with specific demands in this regard being placed on the upper and lower connecting locations of the semiconductor, which are subjected to high thermal and electrical requirements. In a customary manner, the top side of the semiconductor is often optimized with a metallization for a bonding process for thick aluminium wires, it being known that the failure of the aluminium wires on the top side of such a semiconductor often constitutes the limiting factor. With the known power semiconductor chip and the method for producing it, the intention is to improve the lifetime and thus the yield by means of a more stable implementation that is less at risk of fracture. In the case of this prior art, this is realised by an embodiment of the top-side contact-connection as thick-wire copper bonding technology, which not only makes possible increased mechanical loads but also makes possible a significant increase in the current-carrying capacity and endurance to withstand alternating loads. Shaped bodies composed of copper, silver, gold, molybdenum, tungsten and their alloys with a thickness of 30 μm to 300 μm are used for this purpose.

DE 20 20012 004 434 U1 describes a metal shaped body which serves to produce a connection of a power semiconductor chip having top-side potential areas to thick wires. In comparison with the regularly used aluminium wire bonding technology on the top side of the semiconductor, wherein the aluminium wires fail particularly in the event of overloading, this prior art involves orientation towards metal shaped bodies having good electrical and thermal conductivity and likewise composed of copper, silver, gold, aluminium, molybdenum, tungsten and their alloys with a thickness of 30 μm to 300 μm, wherein copper thick wire bonding with wire diameters of up to 600 μm diameter is preferably used. The relatively thick metal shaped body thus affords the possibility of using, precisely even for thin semiconductor elements, thick copper wires and copper ribbons for contact-connection on their top side, specifically because the metal shaped bodies protect the sensitive thinly metallized surfaces of the semiconductors by means of bonding with copper thick wire. By virtue of their heat capacity, the known metal shaped bodies provide more uniform heating and thus constitute a heat buffer.

What is common to all these power semiconductor components and the methods for producing them is that the prior art describing them does not address the topic of avoiding explosions. The publication “Explosion Tests on IGBT High Voltage Modules” by Gekenidis et al., Reprint from the International Symposium and Power Semiconductor Devices and ICs, May 1999, Toronto, Canada, describes for wire-bonded modules how the protection thereof when explosions occur can be increased. The publication describes that plasma can occur in the housing as a result of a short circuit, which plasma must not penetrate towards the outside in order that e.g. inverters cannot be damaged. Therefore, the publication merely describes that the housings are intended to be embodied such that they are correspondingly explosion-proof; an explosion-proof design of the IGBT modules is not described. Furthermore, the plasma generated by an arc and having temperatures of up to 20 000° C. can decompose even incombustible materials of the internal insulation and produce an explosive gas mixture, and so this known solution is not safe at very high released energies.

The conference paper “Explosion Proof Housings for IGBT Module based High Power Inverters in HVDC Transmission Application”, by Billmann et al., Proceedings PCIM Europe 2009 Conference likewise describes that, in the case of wire-bonded IGBT modules, the intention is to increase their lifetime and capability to withstand alternating loads, and that damage to an inverter can occur on account of overload conditions because the IGBTs explode. Therefore, attention is devoted to researching the causes of the explosion, which consist in the formation of arcs, and described measures for minimizing the consequences of explosions occurring in IGBTs include an improved design of housings in the sense of explosion-proof housings with higher stiffness. Therefore, only mechanical structure improvements on the housing are described. Semiconductor components with direct pressure contact technology are described in “Halbleiter-Leistungsbauelemente: Physik, Eigenschaften, Zuverlässigkeit” by Josef Lutz, Springer-Verlag GmbH, 2012 (Lutz). Such thyristors (shown in FIG. 4.3 of Lutz) and IGBTs (in FIG. 4.4) are already deemed to be explosion-proof, since a large-area connection of high current-carrying capacity forms there and the semiconductor chip that breaks down reliably short-circuits.

However, even with constructions such as are illustrated in FIG. 4.10 of Lutz for a thyristor module using soldering technology, generally the failure is not associated with an explosion. Here, too, the semiconductor body breaks down. A large-area soldered upper contact-connection and a soldered connection with a copper plate of sufficient thickness enable a current to be carried even after the failure, although this is not specified in any further detail. For IGBTs, however, such designs are not customary and cannot readily be applied to the design thereof. Primarily, however, no parallel circuits are accommodated in these thyristor housings, in contrast to housings with modern IGBTs, but parallel circuits are generally present in the power semiconductor module field.

### SUMMARY

Against this background, the object of the present invention is to provide power semiconductor modules and power semiconductor structures comprising at least one power semiconductor module of this type which permit a so-called robust short-circuit failure mode in such a way that explosions of the power semiconductor module are avoided.

According to the invention, the power semiconductor module is embodied such that it can be transferred from an operating mode to an explosion-free robust short-circuit failure mode, which is also designated as SCFM. The power semiconductor module according to the invention comprises a semiconductor, which is e.g. an IGBT or some other power component and has metallizations forming potential areas at its top side, said metallizations being separated by insulations and passivations. On an electrically conductive connecting layer furthermore provided, a metal shaped body is applied by sintering such that said metal shaped body is materially bonded to the respective potential area. The metal shaped body is embodied such that it is significantly thicker than the connecting layer and has a low lateral electrical resistance. According to the invention, the metal shaped body has means for laterally homogenizing the current flowing through it in such a way that its lateral current flow component is maintained, to be precise without the metal shaped body, the connections having high-current capability that are fitted thereon and parts of the power semiconductor module that are connected thereto incurring damage. A transition from the operating mode to the robust short-circuit failure mode takes place in an explosion-free manner by virtue of the fact that the connections are contact-connected and dimensioned such that, in the case of overcurrent loads of greater than a multiple of the rated current of the power semiconductor module, the operating mode undergoes transition to the short-circuit failure mode (SCFM), to be precise with connections remaining on the metal shaped body without the formation of arcs, such that the transition from the operating mode to the short-circuit failure mode changes in an explosion-free manner. The avoidance of arc-formation is a significant advantage, since the presence of the high temperature ionised gas of which an arc is formed is likely to trigger an explosion either by igniting an explosive atmosphere, or by causing the destruction of packaging through uncontrolled thermal expansion. The connections having high-current capability have, with respect to the metal shaped body, a minimum cross-sectional area A, the size of which is calculated on the basis of the product of the current I_{wc} in the worst case, i.e. the least favourable conditions, and a coefficient ζ in the range of 1×10⁻⁴ to 5×10⁻⁴ mm²/A.

Preferably, the current I_{wc} in the worst case is calculated on the basis of the product of twice the rated current of the power semiconductor module and the number of chips per module.

Preferably, a fuse connected to an electric circuit of the power semiconductor module is provided. The power semiconductor module changes to the robust short-circuit failure mode in an explosion-free manner until the fuse has tripped and the overload current is switched off. The fuse requires a certain time for its reaction, in order to disconnect the power semiconductor module from the current source. The power semiconductor module is therefore dimensioned such that, owing to the customary inertia of the fuses, the robust short-circuit failure mode bridges at least the inertia times of the fuse. A fuse in this connection may comprise a sacrificial device which requires replacing after the clearing of the fault, or a resettable device such as a circuit breaker.

In contrast to the prior art, which is merely directed to designing the housings such that, in the case of an explosion e.g. of an IGBT that occurs during operation, only the forces released by the explosions are absorbed by the housing, with the result that damage to adjacent modules and components e.g. in a complete stack is avoided, that is to say that the housing of the power semiconductor prevents damage owing to the explosion from spreading, the present invention involves choosing a construction such that explosions do not even occur in the first place. This is achieved primarily by homogenizing the lateral current flow in the metal shaped body, to be precise preferably at least until a fuse present switches off the power semiconductor module, which can be realised before an explosion.

Preferably, the metal shaped body has a size or an extent such that at least 70% to preferably 95%, if appropriate 100%, of the metallizations on the power semiconductor are covered. On account of the fact that the metal shaped body thus not only has a correspondingly necessary thickness significantly greater than that of the connecting layer but also has an areal extent that is as great as possible, the lateral current flow can be homogenized. This is in turn a basic prerequisite for the power semiconductor module according to the invention embodied in an explosion-free manner.

In accordance with a further preferred embodiment, the power semiconductor module is dimensioned such that a ratio of connection cross-sectional area to connection contact area plus connection contact circumference multiplied by the thickness of the metal shaped body is in a range of 0.05 . . . 1.0. For an explosion-free embodiment of the power semiconductor module, therefore, it is preferable that the dimensioning specification indicated is in the range of the defined ratio. What is important, therefore, is that the cross-sectional area of the connections, and likewise the contact area formed by the connections, despite the restricted available space present, are as large as possible. For determining the ratio indicated, the circumference of the connection contacts and the actual thickness of the metal shaped body are also incorporated into the ratio, i.e. into the dimensioning specification. This has the advantage that the metal shaped body, which is arranged over a large area and is relatively thick relative to the semiconductor, additionally protects the semiconductor and also ensures that so-called thick wires or thick connections of other embodiments can be permanently mechanically and electrically connected to the metal shaped body reliably with correspondingly large contact area.

In further preferred embodiments, the metal shaped body and the connections consist of the same material, preferably copper, and the connections form a mono-metal contact with respect to the metal shaped body. This involves a specific application in the construction and connecting technology of microelectronic systems. A mono-metallic joining connection should be understood to be one which forms no intermetallic phases. This connecting technique is used primarily for stacking thinned chips in the wafer assemblage in order to enable extremely small construction heights and thus extremely high packing densities in conjunction with low thermal loading and maximum reliability of the connection produced, inter alia also owing to the avoidance of intermetallic phases.

In a further embodiment, connections used are thick wires, ribbons or straps fixed to the metal shaped body by means of bonding.

The cross-sectional area A of the individual connection, or the sum of the cross-sectional areas of a plurality of connections, is chosen such that even in the case of the customary parallel circuit in modules—which may have up to 24 individual chips—the connections do not melt through, at least for a certain period. For this purpose, in the worst case the connection of a component must accept the current of all 24 chips without generating an arc as a result of vaporisation. If said chips have a rated current of 150 A, for example, and if double the rated current is assumed, then 7200 A results as momentary current-carrying capacity I_{wc} in the worst case.

In accordance with one embodiment of the invention, the metal shaped body is embodied with a varying thickness in terms of its areal extent, in particular that the thickness prevailing in its edge regions is less than that prevailing in its central region. In this case, the variation of the thickness of the metal shaped body can be embodied in a stepped manner or with continuous transitions. Preferably, the thickness of the metal shaped body decreases from the centre of said metal shaped body towards the edge regions thereof, in particular either continuously or in a stepped manner. The different thickness of the metal shaped body at the edge regions thereof in comparison with that at least in the region with respect to the central region thereof serves, inter alia, for further homogenizing the lateral current flow by adapting the electrical resistance of the metal shaped body. Such an embodiment also has further thermochemical advantages to the effect that the mechanical stress between the silicon and the metal shaped body is reduced.

Preferably, the metal shaped bodies can also have cutouts in the form of holes or slots, e.g. in order to minimize the thermomechanical stresses between metal shaped body and semiconductor. However, said cutouts should be dimensioned and arranged in such a way that they do not appreciably impede the lateral current flow component. Advantage is thus attached, for example, to slots or series of holes directed in a star-shaped manner, instead of those arranged on sectors of concentric circles.

Preferably, the power semiconductor module according to the invention is embodied such that the multiple of the rated current of the power semiconductor is in the range of 1000 to 1500 A, if appropriate even higher.

In accordance with yet another embodiment of the invention, the metal shaped body preferably has, on its side facing the connecting layer, an area that is larger than the area of the electrical connection to the associated potential area. The metal shaped body, with its overhang resulting from its larger area, is fixed with said overhang on an organic, non-conductive carrier film. The advantage of a metal shaped body that is as large as possible is that homogenization of the lateral current flow can be realised all the better, the larger the embodiment of said metal shaped body.

Preferably, the carrier film is embodied or has a size such that it adhesively covers regions of the surface of the power semiconductor that are not to be joined. The carrier film thus protects a region of the power semiconductor on which no further elements are joined.

Preferably, the power semiconductor of the power semiconductor module is embodied such that it has a respective metal shaped body both on its top side and on its underside. In other words, in addition to the top-side metal shaped body, a further metal shaped body is arranged on the underside of the power semiconductor, wherein the further metal shaped body is connected to the power semiconductor by means of a further electrical connecting layer produced by low-temperature sintering, in particular silver low-temperature sintering. The compactness of the power semiconductor module can thus be increased further.

In accordance with one development of the invention, a plurality of top-side potential areas provided with potentials can also be provided on the power semiconductor module, on which potential areas there are arranged in each case a number of metal shaped bodies corresponding to the number of potential areas.

In the prior art, aluminium is provided as material for the metallization layer and also for the connections in broad application, and normally this precisely does not ensure explosion-proof protection. In the case of a defective semiconductor cell which acquires low impedance owing to a defect and draws the entire load current, the relatively small cross section of the aluminium metallization leads locally to its evaporation, which causes the wires to lift off therefrom at a very early point in time, thus giving rise to the growth of an arc with the consequence of an explosion. Preferably, the power semiconductor module according to the invention furthermore provides, then, for the metal shaped body to consist of a material having a melting point of at least 300 K higher than that of aluminium, in particular, copper, silver, gold, molybdenum, tungsten or an alloy thereof, and wherein the connecting layer has a comparably high melting point and consists, in particular, of silver, copper or gold. The significantly higher melting point compared with aluminium significantly reduces or even prevents arcs that cause explosions from arising.

The power semiconductor modules are generally arranged in an assemblage and provided with fuses, preferably arranged externally. The task of the fuse is, in the event of overcurrents significantly above the rated current, to ensure a switch-off of the respective power semiconductor module in an assemblage of a plurality of such modules, to be precise before an explosion caused by an arc occurs in the interior of such a power semiconductor module.

In accordance with a further aspect of the invention, the power semiconductor module in accordance with the features according to the embodiments herein previously described is used in environments endangered by explosion, in particular in control units for wind power installations. In the case of control units for wind power installations, for example, numerous power semiconductor modules are joined together to form power semiconductor. It is important in such an installation that in the case of the short circuit of a single semiconductor module, power semiconductor modules and components adjacent thereto are not detrimentally affected.

### BRIEF DESCRIPTION OF THE DRAWINGS

Further advantages, features and possible applications of the present invention will now be explained with reference to the accompanying drawings. In the drawings:

FIG. 1 shows a simplified illustration of a defective semiconductor module of known design;

FIG. 2 shows a simplified illustration of a defective semiconductor module with a basic illustration of the embodiment according to the invention with a so-called DBB (metal shaped body);

FIG. 3 shows three different embodiments of the edge region of the metal shaped body, with further elements of the semiconductor module being omitted for the sake of simplicity;

FIG. 4 shows a simplified illustration of the melting zone that forms in the case of a short circuit;

FIG. 5 shows an embodiment where the metal shaped body has cutouts;

FIG. 6 shows a further embodiment of the invention in which the metal shaped an area larger than that of the electrical connection to the associated potential area; and

FIG. 7 shows a yet further embodiment in which the semiconductor has a metal shaped body both on its top side and on its underside.

### DETAILED DESCRIPTION

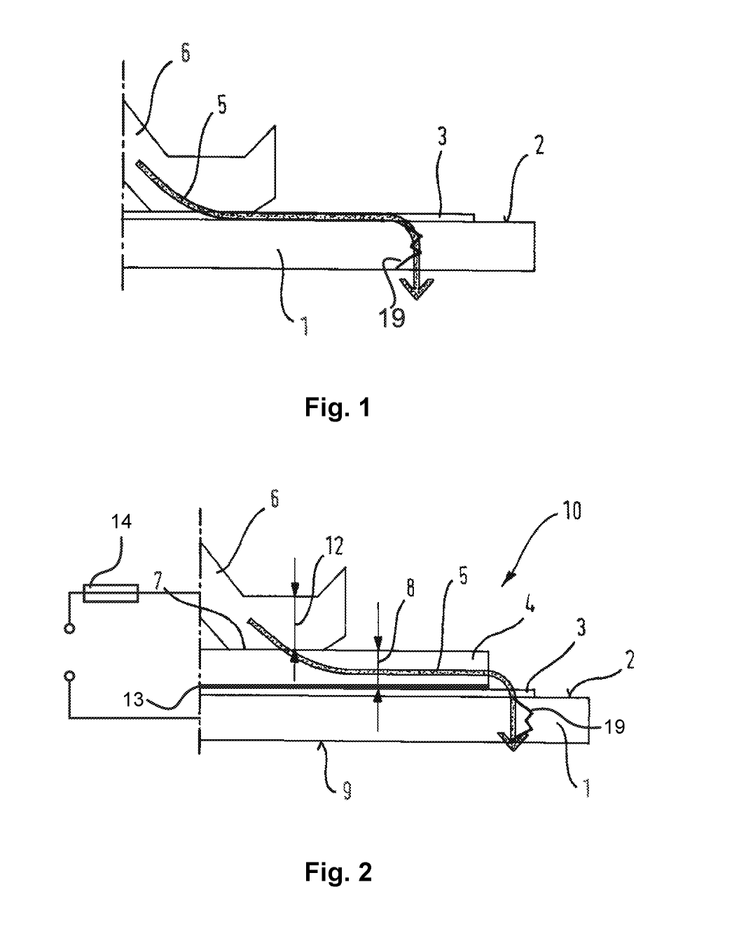

FIG. 1 shows a partial view of a defective semiconductor module in a basic arrangement, in the case of which module a power semiconductor 1 is shown, on which a relatively thin metallization 3 is provided on the top side 2 of the power semiconductor 1. Said metallization 3 serves for the possibility of connecting a preferably aluminium thick wire 6 for the fixing thereof on the metallization 3 by way of thick wire bonding. This arrangement of a semiconductor module corresponds to the known prior art. In the power semiconductor 1, a defect is depicted by a jagged line 19, which defect can have the effect that the basic course—depicted by the arrow—of the current flow 5 leads to the passage thereof through the defect in the power semiconductor 1. In this known arrangement of a power semiconductor cell 1, in the case of the illustrated defect 19 and the use of the thin metallization layer for bonding the aluminium thick wire, the probability of burn-through, on account of the semiconductor properties and the thermal boundary conditions, is highest in that area of the power semiconductor 1 which is not covered by the bonding wire 6. A major problem of these known semiconductor modules is that an explosion can occur on account of their structural embodiment. Since, for control installations, numerous power semiconductor modules 10 are combined in an assemblage, such explosions are feared for a variety of reasons. Firstly, in the event of an explosion, harmful vapours and, owing to the high temperature, plasma occur which can damage or likewise destroy numerous adjacent semiconductor modules and components. An entire control unit can thus become unusable. Secondly, owing to the harmful substances that can be released in the event of an explosion, such an explosion can also entail injury to life and limb of the persons who maintain or operate these control units.

Explosions generally occur if overload currents flow through the individual cells, which may be the case, for example, if a motor controlled by the control unit is blocked. Furthermore, overloads can also occur as a result of the ageing of the elements of the power semiconductor modules 10. During operation, a damaged power semiconductor module 10 will take precedence in heating up first, which as the weakest cell then also fails first or constitutes the module that attains the highest temperature. This semiconductor module locally becomes conductive and acquires no impedance and thereby continues to draw current to itself. In the case of such overload currents, the thin metallization 3 illustrated in FIG. 1 relatively rapidly attains a state of overloading. The bonding wires 6, may have a thickness of approximately 100-500 μm and are welded to the thin metallization layer 3 by means of ultrasonic friction welding or by pressure welding. Such bonding wires have—relative to the circumference of the bonding wire 6—a small extent of a relatively planar connecting area with the metallization layer.

In order that the current is distributed as uniformly as possible in the semiconductor modules, as many wires as possible, i.e. as many connections 6 as possible, are provided within a cell. However, the space requirement of a semiconductor module restricts the number of connections. In the event of an overload, firstly the metallization layer 3 around the region of the direct connections 6 decomposes, for which reason the wires present there lift off relatively rapidly and interrupt an electrical connection. That in turn leads to a higher loading for the remaining wires still connected. Once further wires have become detached, an arc arises upon the detachment of the last wire in a semiconductor module. The extremely high temperatures that arise in an arc have the effect that material evaporates in the region of the arc and a plasma arises, such that the affected semiconductor module explodes with the abovementioned consequences for the entire control unit.

FIG. 2 likewise shows a defective semiconductor module, in which a metal shaped body 4 is arranged on the metallization layer on the top side 2 of the power semiconductor 1, on which metal shaped body a thick wire 6 is fixed to a connection contact area 7. The metal shaped body 4 has a thickness 8 in the range of 100-400 μm, i.e. a thickness that is in the range of the thickness of the bonding wires 6, namely in the range of 100-500 μm. The figure likewise depicts the current flow 5 from the bonding wire 6 via the connection contact area 7 through the metal shaped body 4 with a substantially lateral current flow 5 in said metal shaped body, then emerging from the metal shaped body 4 at the end face through the metallization 3 on the top side 2 of the power semiconductor 1 and, finally, through the defect 19 location of the power semiconductor 1.

Surprisingly, it has now been found that with a relatively thick metal shaped body 4 there is a significantly better manifestation of a lateral current flow component with an easier capability of conducting away even overcurrents by means of an embodiment according to the invention of a semiconductor module in accordance with FIG. 2. On account of the relatively large material thickness, the large amount of material present there, generally copper, has a relatively low electrical resistance in a lateral direction.

It has now been found that with corresponding dimensioning of a semiconductor module with a metal shaped body 4 of the kind as illustrated in FIG. 2, it is possible to ensure freedom from explosions even under overload currents for such a power semiconductor module 10 according to the invention. The reason for this is that by homogenizing the lateral current flow 5, on account of the amount of material in the metal shaped body 4, overload currents can be maintained long enough that a fuse 14 which belongs to the semiconductor module or is connected thereto, and which can also be arranged externally, blows. An explosion can be prevented on account of the lateral current flow 5 being maintained over a significantly longer period of time than in the case of the known connecting structures. The dimensioning of the size of the metal shaped body 4 is also significant for this purpose. Specifically at least 70 to 95% of the emitter area of the power semiconductor 1 is covered with the metal shaped body 4. By means of this measure a delay of an explosion of approximately 300 μs is achieved, which is sufficient for an associated fuse to blow. The parameters/size of the connection cross-sectional area, size of the connection contact area and size of the connection contact circumference and the thickness of the metal shaped body 4 therefore play a part for the homogenization. Firstly, the connection contact area 7 can be larger than in the case of an embodiment in accordance with FIG. 1 because when the bonding wire 6 is connected to the metal shaped body 4 at the connection contact location 7, the bonding wire 6 can bond better to the metal shaped body 4 and can produce with the latter an actual contact area which extends over a larger circumferential region of the bonding wire 6 than is the case in the exemplary embodiment in accordance with the prior art according to FIG. 1. If the ratio of connection cross-sectional area to connection contact area plus the connection contact circumference multiplied by the thickness of the metal shaped body is of an order of magnitude of 0.05-1, structural measures are provided which surprisingly lead to explosion-free operation of the semiconductor modules, even if the latter have defect locations.

With regard to the dimensioning, the computational estimation, simplified below, can be applied.

The minimum cross-sectional area A of the connection 6, which has the thickness 12 and which can consist of one piece or of many individual connectors guided parallel, is designed such that it satisfies the relationship

$$A = \sqrt{\frac{ρ \cdot {t}_{p}}{Δ T \cdot {C}_{spec}}} \cdot {I}_{wc} \qquad ( 1 )$$

wherein ρ is the resistivity, tₚ is the pulse length until the end of the overcurrent event or tripping of a fuse, ΔT is the possible increase in temperature from the operating temperature Tₒₚ until the melting temperature Tₘₑₗₜ is reached

ΔT=Tₘₑₗₜ−Tₒₚ (2)

C_{spec} is the specific heat capacity of the material used and I_{wc} is the described current in the worst case, which results for example from

I_{wc}=2*rated current of the module*number of chips in parallel per module (3)

Materials having high electrical conductivity such as Cu, Ag, Au but also Al are expedient here.
The above estimation can be simplified as

A=ζ*I_{wc} (4)

For ζ with the use of Cu and Ag and with a design at tₚ=10 ms, the following range arises
ζ=0.0001 to 0.0005 mm²/A,
   and with the use of gold, on account of the poorer electrical conductivity and lower specific heat, the following range arises
ζ=0.00015 to 0.0008 mm²/A,
   with the use of Al, on account of the lower melting temperature of Al and other parameters contained in equation (1), the same estimation results in the range
ζ=0.0002 to 0.001 mm²/A.
   That is double the cross-sectional area compared with Cu and Ag, but this is technically more difficult to realise owing to restricted space capacity in the module.

By way of example, a module has a rated current of 3600 A and 24 chips are connected in parallel therein. In the worst case, a connector has to carry double the rated current over 10 ms, this being 7200 A. The minimum cross-sectional area of the connector then has to be between 0.72 mm² and 3.6 mm² with the use of Cu or Ag. This area can be achieved by one planar piece or by different individual parallel bonding wires.

For particularly compact configurations of semiconductor modules or power semiconductor modules 10 it is also possible for the actual power semiconductor 1 to bear a metal shaped body 4 not only at its top side 2 on a metallization layer 3 arranged thereon, rather it is also possible for a metallization layer 3 likewise to be provided on the underside 9 of the power semiconductor 1, a further metal shaped body 4 being connected to said metallization layer. In order to ensure a corresponding freedom from explosions, said further metal shaped body should, of course, be designed under analogous design parameters.

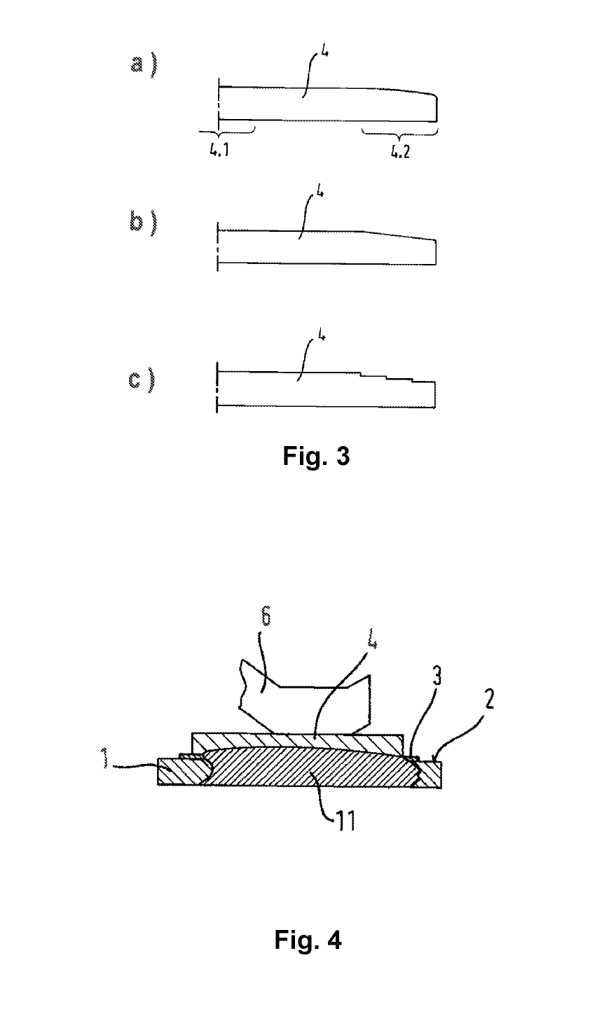

In accordance with a further exemplary embodiment of the invention, as illustrated in FIG. 3, the metal shaped body 4 has a form in which its thickness in the central region 4.1 differs from that in the edge region 4.2. The variation of the thickness 8 of the metal shaped body 4 in the edge region 4.2 in this case is such that in the edge region 4.2 this thickness 8 is embodied as a continuous decrease in thickness from the maximum thickness 8 of the metal shaped body 4 directly towards the edge (see FIG. 3a).

In FIG. 3b), this continuous decrease in the thickness in the edge region 4.2 is a linear decrease. In the edge region 4.2 in accordance with FIG. 3c), the decrease in the thickness is realised by a stepped embodiment. Relative to the thickness of the bonding wire 6, the decrease in the thickness in the edge region 4.2 is relatively small and is in the range of approximately 1-5 μm.

FIG. 4 illustrates a melting zone 11. This melting zone arises between the metal shaped body 4, the metallization layer 3 (together with the connecting layer 13) and the silicon chip 1. The melting zone 11 arises as a result of a very high current concentration in the region of the defect and heat that arises as a result. The melting zone has a low resistance and can carry the short-circuit current over a relatively long time, to be precise without the formation of an arc which, in known power semiconductor modules, can lead to the explosion thereof.

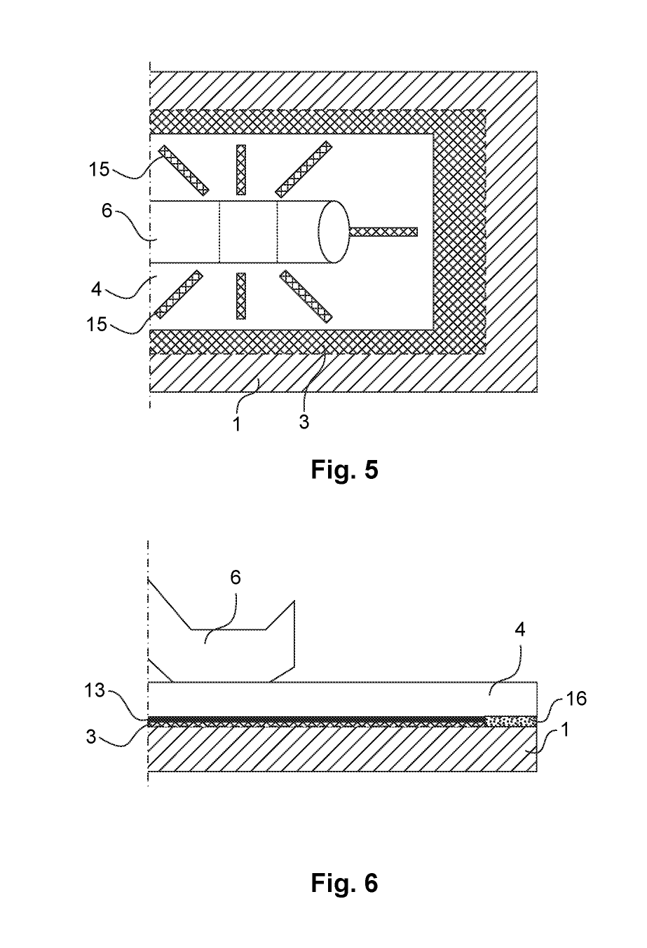

FIG. 5 illustrates an embodiment where the metal shaped body 4 has cutouts in the form of elongated holes or slots 15. This is an advantage in order to minimize the thermomechanical stresses between metal shaped body 4 and semiconductor 1. Such slots 15 are dimensioned and arranged in such a way that they do not appreciably impede the lateral current flow component. Here the slots 15 are directed in a star-shaped manner.

FIG. 6 illustrates a further embodiment of the invention in which the metal shaped body 4 has, on its side facing the connecting layer 13, an area that is larger than the area of the electrical connection to the associated potential area. The metal shaped body 4, with its overhang resulting from its larger area, is fixed with said overhang on an organic, non-conductive carrier film 16. The advantage of a metal shaped body 4 that is as large as possible is that homogenization of the lateral current flow can be realised all the better, the larger the embodiment of said metal shaped body.

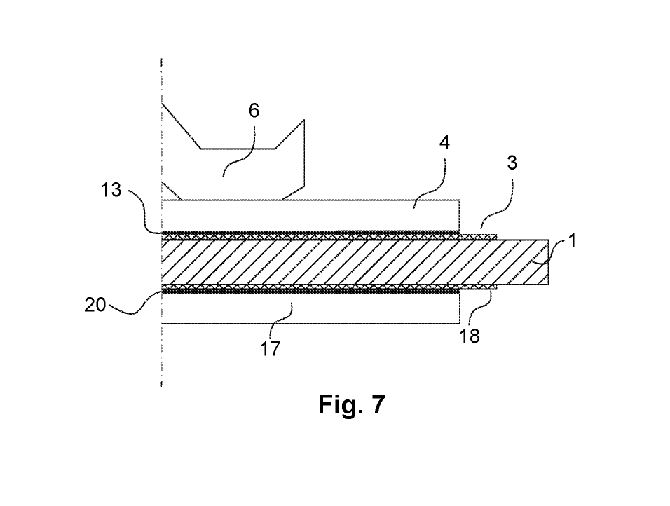

FIG. 7 illustrates a yet further embodiment which semiconductor 1 has a metal shaped body 4, 17 both on its top side and on its underside. In other words, in addition to the top-side metal shaped body 4, a further metal shaped body 17 is arranged on the underside of the power semiconductor 1, wherein the further metal shaped body 17 is connected to the power semiconductor by means of a further electrical connecting layer 20 produced by low-temperature sintering, in particular silver low-temperature sintering. The compactness of the power semiconductor module can thus be increased further.

While the present disclosure has been illustrated and described with respect to a particular embodiment thereof, it should be appreciated by those of ordinary skill in the art that various modifications to this disclosure may be made without departing from the spirit and scope of the present disclosure.

What is claimed is:

1. A power semiconductor module, which can be transferred from an operating mode to an explosion-free robust short-circuit failure mode and comprises:
a power semiconductor having metallizations which form at least one potential area and are separated by insulations and passivations at the top side of said power semiconductor,
an electrically conductive connecting layer,
on which at least one metal shaped body which has a low lateral electrical resistance and is significantly thicker than the connecting layer is applied by sintering such that it is materially bonded to the respective potential area,
wherein the metal shaped body has means for laterally homogenizing a current flowing through it in such a way that a lateral current flow component is maintained, and wherein the metal shaped body bears at least one connection having high-current capability,
and wherein a transition from the operating mode to the robust short-circuit failure mode takes place in an explosion-free manner by virtue of the fact that the connections are contact-connected and dimensioned in such a way that,
in the case of an overload current of greater than a multiple of the rated current of the power semiconductor the operating mode changes to the short-circuit failure mode in an explosion-free manner with connections remaining on the metal shaped body without the formation of arcs, and
the connection with respect to the metal shaped body is equipped with a minimum cross-sectional area A, wherein A is determined from the product of current I_{wc} in the worst case and ζ, wherein ζ is in the range of 0.0001 to 0.0005 mm²/A.

2. The power semiconductor module according to claim 1, which comprises a fuse connected to an electric circuit of the power semiconductor module, and changes to the robust short-circuit failure mode in an explosion-free manner in the case of the overload current until the fuse has tripped and the overload current is switched off.

3. The power semiconductor module according to claim 1, wherein the connection is composed of silver, copper, gold or aluminium.

4. The power semiconductor module according to claim 1, wherein the metal shaped body covers at least 70% to 100% of the metallizations which form potential areas.

5. The power semiconductor module according to claim 1, wherein a ratio of connection cross-sectional area to connection contact area plus connection contact circumference multiplied by the thickness of the metal shaped body is in the range of 0.05 to 1.

6. The power semiconductor module according to claim 1, wherein the metal shaped body and the connections consist of the same material and the connections form a mono-metal contact with respect to the metal shaped body.

7. The power semiconductor module according to claim 6, wherein the connections are thick wires, ribbons, or straps which are fixed by means of bonding, or springs which are contact-connected by pressure.

8. The power semiconductor module according to claim 1, wherein the metal shaped body has a thickness varying over its area in such a way that there is a smaller thickness in the edge regions of said metal shaped body than in the central region thereof.

9. The power semiconductor module according to claim 1, wherein the thickness of the metal shaped body decreases continuously from the centre of said metal shaped body to the edge regions thereof.

10. The power semiconductor module according to claim 1, wherein the thickness of the metal shaped body decreases in a stepped manner from the centre of said metal shaped body to the edge regions thereof.

11. The power semiconductor module according to claim 1, wherein, in addition to or instead of the varying thickness of the metal shaped body, cutouts that do not appreciably impede the lateral current flow component. are provided in the metal shaped bodies.

12. The power semiconductor module according to claim 1, wherein the multiple of the rated current of the power semiconductor is in the range of 1000 to 1500 A.

13. The power semiconductor module according to claim 1, wherein the metal shaped body has, on its side facing the connecting layer, an area which is larger than the area of the electrical connection to the associated potential area, and the metal shaped body is fixed with its overhang on an organic, non-conductive carrier film.

14. The power semiconductor module according to claim 13, wherein the carrier film adhesively covers regions of the surface of the power semiconductor that are not to be joined.

15. The power semiconductor module according to claim 1, wherein, in addition to the top-side metal shaped body, a further metal shaped body is provided on the underside of the power semiconductor and is connected to the power semiconductor by means of a further connecting layer produced by sintering, in particular silver sintering.

16. The power semiconductor module according to claim 1, wherein a number of metal shaped bodies corresponding to the number of top-side potential areas provided with the potentials are provided on the top side of the power semiconductor.

17. The power semiconductor module according to claim 1, wherein the metal shaped body consists of a material having a melting point of at least 300 K higher than that of aluminium, in particular a material from the group Cu, Ag, Au, Mo, W or the alloys thereof, and the connecting layer has a comparably high melting point and consists in particular of a material from the group Ag, Cu, Au.

18. The power semiconductor module according to claim 1, wherein the fuse is arranged externally.

19. Use of a power semiconductor module comprising the features according to claim 1 in environments endangered by explosion.

20. The power semiconductor module according to claim 2, wherein the connection is composed of silver, copper, gold or aluminium.
